(19) United States
(12) Patent Application Publication
(10) Pub. No.: US 2025/0275338 A1
(43) Pub. Date: Aug. 28, 2025

(54) DISPLAY DEVICE

(71) Applicant: LG Display Co., Ltd., Seoul (KR)

(72) Inventors: Seokho SHIM, Paju-si (KR); Jinho CHO, Paju-si (KR)

(21) Appl. No.: 19/024,847

(22) Filed: Jan. 16, 2025

(30) Foreign Application Priority Data
Feb. 26, 2024 (KR) 10-2024-0027248

(51) Int. Cl. H10H 29/49; H10H 29/32; H10H 29/80; H10H 29/855

(52) U.S. Cl. CPC H10H 29/49; H10H 29/32; H10H 29/8325; H10H 29/855

(57) ABSTRACT

A display device includes pixels, a light-blocking layer, and transistors disposed in the pixels and on the light-blocking layer. Reflective electrodes are on the transistors. Light emitting elements are disposed in the pixels and on the reflective electrodes. Power lines are on the substrate. Power lines each includes a first sub-power line extending in a first direction and disposed on a same layer as the light-blocking layer; a second sub-power line extending in a second direction different from the first direction and disposed on a same layer as electrodes of the plurality of transistors; and a third sub-power line extending in the first direction and disposed on a same layer as the plurality of reflective electrodes.

### CROSS-REFERENCE TO RELATED APPLICATIONS

This application claims the priority of Korean Patent Application No. 10-2024-0027248 filed on Feb. 26, 2024, in the Korean Intellectual Property Office, the disclosure of which is incorporated herein by reference.

### BACKGROUND

### Technical Field

The present disclosure relates to a display device, and more particularly, to a display device using a light emitting diode (LED).

### Description of the Related Art

As display devices which are used for a monitor of a computer, a television, a cellular phone, or the like, there are an organic light emitting display (OLED) device which is a self-emitting device, a liquid crystal display (LCD) device which requires a separate light source, and the like.

An applicable range of the display device is diversified to personal digital assistants as well as monitors of computers and televisions and a display device with a large display area and a reduced volume and weight is being studied.

Further, recently, a display device including a light emitting diode (LED) is attracting attention as a next generation display device. Since the LED is formed of an inorganic material, rather than an organic material, reliability is excellent so that a lifespan thereof is longer than that of the liquid crystal display device or the organic light emitting display device. Further, the LED has a fast lighting speed, excellent luminous efficiency, and a strong impact resistance so that a stability is excellent and an image having a high luminance can be displayed.

### BRIEF SUMMARY

Various embodiments of the present specification provide a display device with improved luminance uniformity.

Various embodiments of the present specification provide a display device capable of solving a problem of a voltage drop.

Various embodiments of the present specification provide a display device with an improved lifespan.

Technical benefits of the present disclosure are not limited to the above-mentioned benefits, and other benefits, which are not mentioned above, can be clearly understood by those skilled in the art from the following descriptions.

According to an aspect of the present disclosure, there is provided a display device. The display device comprises a substrate on which a plurality of pixels is defined; a light-blocking layer disposed on the substrate; a plurality of transistors disposed in the plurality of pixels and on the light-blocking layer; a plurality of reflective electrodes disposed on the plurality of transistors; a plurality of light-emitting elements disposed in the plurality of pixels and on the plurality of reflective electrodes; and a plurality of power lines disposed on the substrate, wherein the plurality of power lines each comprises: a first sub-power line extending in a first direction and disposed on the same layer as the light-blocking layer; a second sub-power line extending in a second direction different from the first direction and disposed on the same layer as electrodes of the plurality of transistors; and a third sub-power line extending in the first direction and disposed on the same layer as the plurality of reflective electrodes.

Other detailed matters of the exemplary embodiments are included in the detailed description and the drawings.

According to the present specification, the power line having the mesh structure is disposed, which may reduce or minimize voltage deviation.

According to the present specification, it is possible to improve luminance uniformity of the light-emitting element by reducing a voltage deviation.

According to the present specification, it is possible to reduce an RC delay by reducing resistance of the power line.

According to the present specification, it is possible to suppress a burnt display panel that may be caused by the occurrence of static electricity.

The effects according to the present disclosure are not limited to the contents exemplified above, and more various effects are included in the present specification.

### BRIEF DESCRIPTION OF THE SEVERAL VIEWS OF THE DRAWINGS

The above and other aspects, features and other advantages of the present disclosure will be more clearly understood from the following detailed description taken in conjunction with the accompanying drawings, in which:

FIG. 1 is a schematic configuration view of a display device according to an embodiment of the present specification;

FIG. 2A is a partial cross-sectional view of the display device according to the embodiment of the present specification;

FIG. 2B is a perspective view of a tiling display device according to the embodiment of the present specification;

FIG. 3 is an enlarged top plan view of the display device according to the embodiment of the present specification;

FIG. 4 is a cross-sectional view of the display device according to the embodiment of the present specification;

FIG. 5 is a cross-sectional view taken along lines A-A′ and B-B′ in FIG. 3; and

FIG. 6 is a cross-sectional view taken along lines C-C′ and D-D′ in FIG. 3.

### DETAILED DESCRIPTION

Advantages and characteristics of the present disclosure and a method of achieving the advantages and characteristics will be clear by referring to exemplary embodiments described below in detail together with the accompanying drawings. However, the present disclosure is not limited to the exemplary embodiments disclosed herein but will be implemented in various forms. The exemplary embodiments are provided by way of example only so that those skilled in the art can fully understand the disclosures of the present disclosure and the scope of the present disclosure.

The shapes, sizes, dimensions (e.g., length, width, height, thickness, radius, diameter, area, etc.), ratios, angles, number of elements, and the like illustrated in the accompanying drawings for describing the embodiments of the present disclosure are merely examples, and the present disclosure is not limited thereto.

A dimension including size and a thickness of each component illustrated in the drawing are illustrated for convenience of description, and the present disclosure is not limited to the size and the thickness of the component illustrated, but it is to be noted that the relative dimensions including the relative size, location, and thickness of the components illustrated in various drawings submitted herewith are part of the present disclosure.

Further, in the following description of the present disclosure, a detailed explanation of known related technologies may be omitted to avoid unnecessarily obscuring the subject matter of the present disclosure. The terms such as “including,” “having,” and “consist of” used herein are generally intended to allow other components to be added unless the terms are used with the term “only”. Any references to singular may include plural unless expressly stated otherwise.

Components are interpreted to include an ordinary error range even if not expressly stated.

When the position relation between two parts is described using the terms such as “on,” “above,” “below,” and “next,” one or more parts may be positioned between the two parts unless the terms are used with the term “immediately” or “directly.”

When an element or layer is disposed “on” another element or layer, another layer or another element may be interposed directly on the other element or therebetween.

When it is mentioned that a first element “is connected or coupled to”, “contacts or overlaps” etc. a second element, it should be interpreted that, not only can the first element “be directly connected or coupled to” or “directly contact or overlap” the second element, but a third element can also be “interposed” between the first and second elements, or the first and second elements can “be connected or coupled to”, “contact or overlap”, etc. each other via a fourth element. Here, the second element may be included in at least one of two or more elements that “are connected or coupled to”, “contact or overlap”, etc. each other.

Although the terms “first,” “second,” and the like are used for describing various components, these components are not confined by these terms. These terms are merely used for distinguishing one component from the other components. Therefore, a first component to be mentioned below may be a second component in a technical concept of the present disclosure.

Like reference numerals generally denote like elements throughout the specification.

The features of various embodiments of the present disclosure can be partially or entirely adhered to or combined with each other and can be interlocked and operated in technically various ways, and the embodiments can be carried out independently of or in association with each other.

Hereinafter, a display device according to exemplary embodiments of the present disclosure will be described in detail with reference to accompanying drawings.

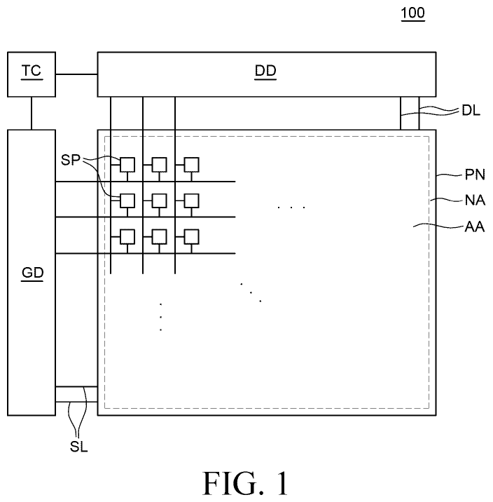

FIG. 1 is a schematic configuration view of a display device according to an embodiment of the present specification. For convenience of description, FIG. 1 illustrates only a display panel PN, a gate driver GD, a data driver DD, and a timing controller TC among various constituent elements of a display device 100.

With reference to FIG. 1, the display device 100 includes the display panel PN including a plurality of subpixels SP, the gate driver GD and the data driver DD configured to supply various types of signals to the display panel PN, and the timing controller TC configured to control the gate driver GD and the data driver DD.

The gate driver GD supplies a plurality of scan signals to a plurality of scan lines SL in response to a plurality of gate control signals provided from the timing controller TC. FIG. 1 illustrates that the single gate driver GD is disposed to be spaced apart from one side of the display panel PN. However, the number and arrangement of the gate driver GD are not limited thereto.

The data driver DD converts image data inputted from the timing controller TC, into a data voltage by using a reference gamma voltage in response to a plurality of data control signals provided from the timing controller TC. The data driver DD may supply the converted data voltage to a plurality of data lines DL.

The timing controller TC aligns image data inputted from the outside, and supplies the image data to the data driver DD. The timing controller TC may generate the gate control signals and the data control signals by using synchronizing signals, i.e., dot clock signals, data enable signals, and horizontal/vertical synchronizing signals inputted from the outside. Further, the timing controller TC may control the gate driver GD and the data driver DD by supplying the generated gate control signals and data control signals to the gate driver GD and the data driver DD.

The display panel PN is configured to display images to a user and includes the plurality of subpixels SP. In the display panel PN, the plurality of scan lines SL, and the plurality of data lines DL intersect one another, and each of the plurality of subpixels SP is connected to the scan line SL and the data line DL. In addition, although not illustrated in the drawings, the plurality of subpixels SP may be respectively connected to a high-potential power line, a low-potential power line, a reference line, and the like.

The display panel PN may have a display area AA, and a non-display area NA configured to surround the display area AA.

The display area AA is an area of the display device 100 in which images are displayed. The display area AA may include the plurality of subpixels SP constituting a plurality of pixels PX, and a circuit configured to operate the plurality of subpixels SP. The plurality of subpixels SP is minimum units that constitute the display area AA. The n subpixels SP may constitute a single pixel PX. A light-emitting element, a thin-film transistor for operating the light-emitting element, and the like may be disposed in each of the plurality of subpixels SP. The plurality of light-emitting elements may be differently defined depending on the type of the display panel PN. For example, in case that the display panel PN is an inorganic light-emitting display panel, the light-emitting element may be a light-emitting diode (LED) or a micro light-emitting diode (micro LED).

A plurality of signal lines for transmitting various types of signals to the plurality of subpixels SP is disposed in the display area AA. For example, the plurality of signal lines may include the plurality of data lines DL for supplying data voltages to the plurality of subpixels SP, and the plurality of scan lines SL for supplying gate voltages to the plurality of subpixels SP. The plurality of scan lines SL may extend in one direction in the display area AA and be connected to the plurality of subpixels SP. The plurality of data lines DL may extend in a direction different from the one direction in the display area AA and be connected to the plurality of subpixels SP. In addition, a low-potential power line, a high-potential power line, and the like may be further disposed in the display area AA. However, the present specification is not limited thereto.

The non-display area NA may be defined as an area in which no image is displayed, i.e., an area extending from the display area AA. The non-display area NA may include link lines and pad electrodes for transmitting signals to the subpixels SP in the display area AA. Alternatively, the non-display area NA may include drive ICs such as gate driver ICs and data driver ICs. The non-display area NA may be positioned on a rear surface of the display panel PN, i.e., a surface on which the subpixel SP is not present. Alternatively, the non-display area NA may be excluded. However, the present specification is not limited to the configuration illustrated in the drawings.

Meanwhile, the drivers such as the gate driver GD, the data driver DD, and the timing controller TC may be connected to the display panel PN in various ways. For example, the gate driver GD may be mounted in the non-display area NA by a gate-in-panel (GIP) method or mounted between the plurality of subpixels SP by a gate-in-active area (GIA) method in the display area AA. For example, the data driver DD and the timing controller TC may be formed on a separate flexible film and a printed circuit board and electrically connected to the display panel PN by a method of bonding the flexible film and the printed circuit board to a pad electrode formed in the non-display area NA of the display panel PN. In case that the gate driver GD is mounted by the GIP method and the data driver DD and the timing controller TC transmit signals to the display panel PN through the pad electrode in the non-display area NA, it is necessary to ensure an area of the non-display area NA in order to dispose the gate driver GD and the pad electrode, which may increase a bezel.

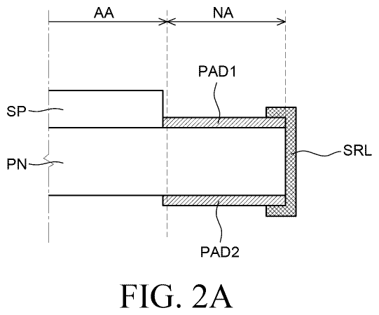

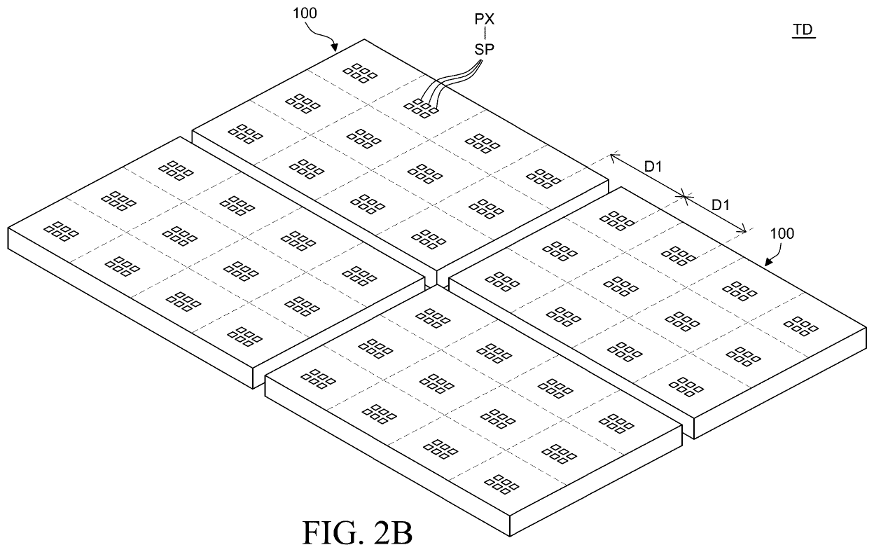

Alternatively, in case that the gate driver GD is mounted in the display area AA by the GIA method and a side line SRL, which connects a signal line on a front surface of the display panel PN to the pad electrode on the rear surface of the display panel PN, is formed to bond the flexible film and the printed circuit board to the rear surface of the display panel PN, it is possible to reduce or minimize the non-display area NA on the front surface of the display panel PN. That is, in case that the gate driver GD, the data driver DD, and the timing controller TC are connected to the display panel PN by the above-mentioned method, a zero bezel in which the bezel is not substantially present may be implemented. A more detailed description will be described with reference to FIGS. 2A and 2B.

FIG. 2A is a partial cross-sectional view of the display device according to the embodiment of the present specification. FIG. 2B is a perspective view of a tiling display device according to the embodiment of the present specification.

A plurality of pad electrodes for transmitting various types of signals to the plurality of subpixels SP is disposed in the non-display area NA of the display panel PN. For example, a first pad electrode PAD1 configured to transmit signals to the plurality of subpixels SP is disposed in the non-display area NA on the front surface of the display panel PN. A second pad electrode PAD2 electrically connected to drive components such as the flexible film and the printed circuit board is disposed in the non-display area NA on the rear surface of the display panel PN.

In this case, although not illustrated in the drawings, various types of signal lines, e.g., the scan line SL, the data line DL, or the like connected to the plurality of subpixels SP may extend from the display area AA to the non-display area NA and be electrically connected to the first pad electrode PAD1.

Further, the side line SRL is disposed along a side surface of the display panel PN. The side line SRL may electrically connect the first pad electrode PAD1 on the front surface of the display panel PN and the second pad electrode PAD2 on the rear surface of the display panel PN. Therefore, the signals received from the drive components on the rear surface of the display panel PN may be transmitted to the plurality of subpixels SP through the second pad electrode PAD2, the side line SRL, and the first pad electrode PAD1. Therefore, a signal transmission route is defined from the front surface to the side surface and the rear surface of the display panel PN, which may reduce or minimize an area of the non-display area NA of the display panel PN.

Further, with reference to FIG. 2B, a tiling display device TD having a large screen may be implemented by connecting a plurality of display devices 100. In this case, as illustrated in FIG. 2A, in case that the tiling display device TD is implemented by using the display device 100 with the reduce or minimized bezel, a seam area in which no image is displayed between the display devices 100 may be reduce or minimized, thereby improving display quality.

For example, the plurality of subpixels SP may constitute a single pixel PX. An interval D1 between an outermost peripheral pixel PX of one display device 100 and an outermost peripheral pixel PX of another display device 100 adjacent to the one display device 100 may be implemented to be equal to the interval D1 between the pixels PX in one display device 100. Therefore, the seam area may be reduce or minimized as a constant interval of the pixels PX is implemented between the display device 100 and the display device 100.

However, as illustrated in FIG. 2A and FIG. 2B, the display device 100 according to the embodiment of the present specification may be a general display device in which the bezel is present. However, the present specification is not limited thereto.

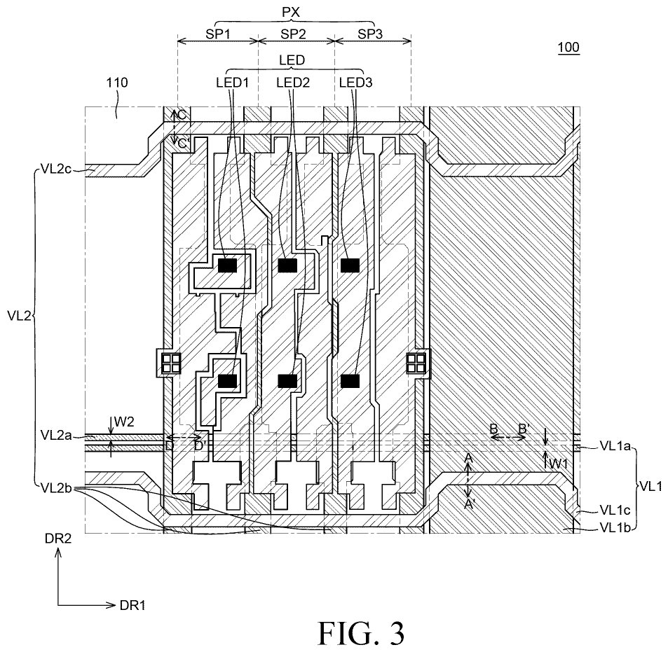

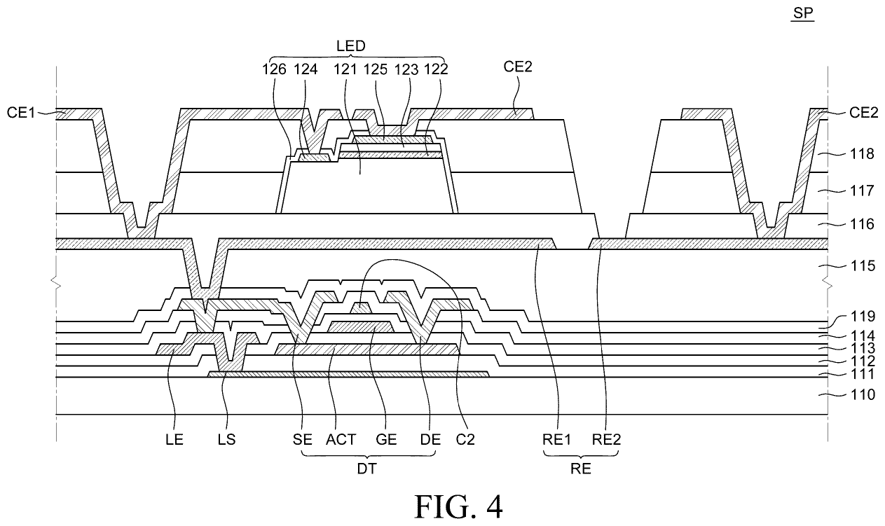

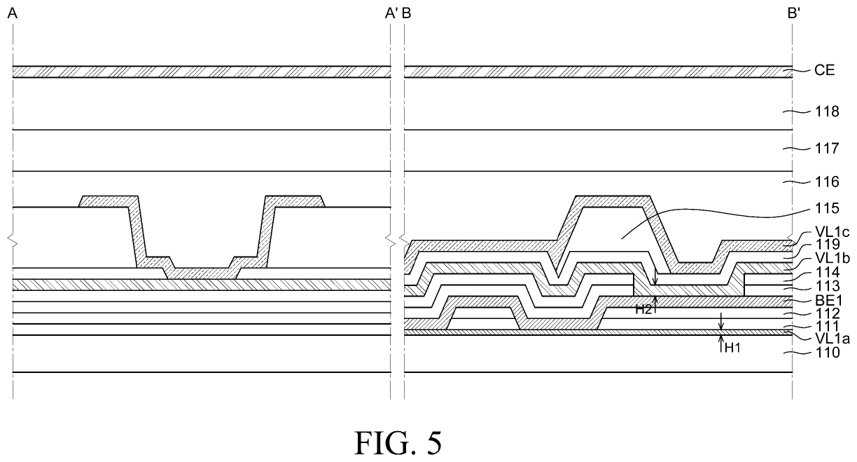

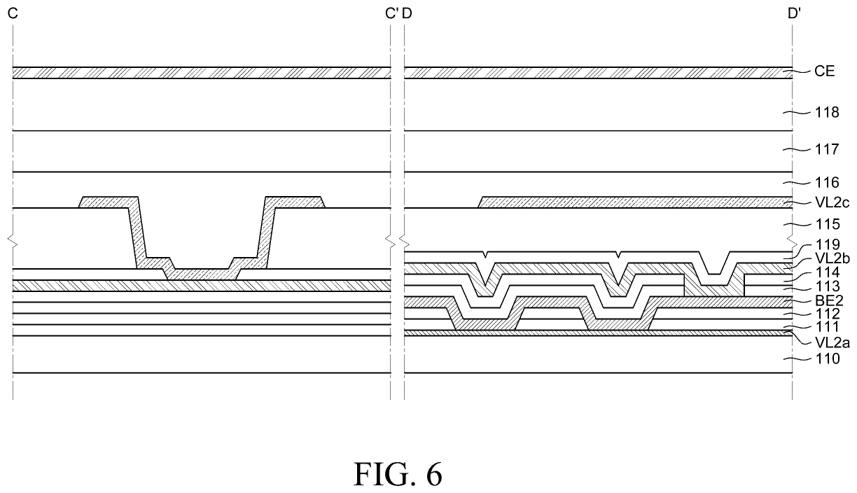

FIG. 3 is an enlarged top plan view of the display device according to the embodiment of the present specification. FIG. 4 is a cross-sectional view of the display device according to the embodiment of the present specification. FIG. 5 is a cross-sectional view taken along lines A-A′ and B-B′ in FIG. 3. FIG. 6 is a cross-sectional view taken along lines C-C′ and D-D′ in FIG. 3. FIG. 5 is a cross-sectional view illustrating a first power line VL1 of the display device 100 according to the embodiment of the present specification. FIG. 6 is a cross-sectional view illustrating a second power line VL2 of the display device 100 according to the embodiment of the present specification.

First, with reference to FIG. 3, the display panel PN may include the plurality of pixels PX each having the plurality of subpixels SP. The plurality of subpixels SP may each include the light-emitting element LED and a pixel circuit and independently emit light. The single pixel PX may include one or more first subpixels SP1, one or more second subpixels SP2, and one or more third subpixels SP3. The first subpixel SP1 may be a red subpixel, the second subpixel SP2 may be a green subpixel, and the third subpixel SP3 may be a blue subpixel. However, the present specification is not limited thereto.

The first subpixel SP1, the second subpixel SP2, and the third subpixel SP3 of the plurality of subpixels SP may be disposed in a first direction DR1.

The plurality of light-emitting elements LED may be respectively disposed in the plurality of subpixels SP. The plurality of light-emitting elements LED may include a first light-emitting element LED1, a second light-emitting element LED2, and a third light-emitting element LED3. For example, the first light-emitting element LED1 may be disposed in the first subpixel SP1, the second light-emitting element LED2 may be disposed in the second subpixel SP2, and the third light-emitting element LED3 may be disposed in the third subpixel SP3. The first light-emitting element LED1 may be a red light-emitting element, the second light-emitting element LED2 may be a green light-emitting element, and the third light-emitting element LED3 may be a blue light-emitting element. However, the present specification is not limited thereto.

The plurality of light-emitting elements LED may be disposed in the first direction DR1. For example, the first light-emitting element LED1, the second light-emitting element LED2, and the third light-emitting element LED3 may be disposed in the first direction DR1.

With reference to FIG. 4, a substrate 110, a buffer layer 111, a gate insulation layer 112, a first interlayer insulation layer 113, a second interlayer insulation layer 114, a first planarization layer 115, a bonding layer 116, a second planarization layer 117, a third planarization layer 118, a passivation layer 119, a driving transistor DT, the light-emitting element LED, a plurality of reflective electrodes RE, a plurality of connection electrodes CE, a light-blocking layer LS, and an auxiliary electrode LE are disposed in each of the plurality of subpixels SP of the display panel PN of the display device 100 according to the embodiment of the present specification.

First, the substrate 110 is a component for supporting various constituent elements included in the display device 100 and may be made of an insulating material. For example, the substrate 110 may be made of glass, resin, or the like. In addition, the substrate 110 may include plastic such as polymer and may be made of a material having flexibility.

The light-blocking layer LS is disposed in each of the plurality of subpixels SP on the substrate 110. The light-blocking layer LS blocks light entering an active layer ACT of the driving transistor DT, which will be described below, from a lower side of the substrate 110. The light-blocking layer LS may block light entering the active layer ACT of the driving transistor DT, thereby reducing or minimizing a leakage current. For example, the light-blocking layer LS may be made of molybdenum (Mo) with high reflection efficiency. However, the present specification is not limited thereto.

The buffer layer 111 is disposed on the substrate 110 and the light-blocking layer LS. The buffer layer 111 may reduce the penetration of moisture or impurities through the substrate 110. For example, the buffer layer 111 may be configured as a single layer or multilayer made of silicon oxide (SiOₓ) or silicon nitride (SiNₓ). However, the present specification is not limited thereto. However, the buffer layer 111 may be excluded in accordance with the type of substrate 110 or the type of transistor. However, the present specification is not limited thereto.

The driving transistor DT is disposed on the buffer layer 111. The driving transistor DT includes the active layer ACT, a gate electrode GE, a source electrode SE, and a drain electrode DE.

The active layer ACT is disposed on the buffer layer 111. The active layer ACT may be made of a semiconductor material such as an oxide semiconductor, amorphous silicon, or polysilicon. However, the present specification is not limited thereto.

The gate insulation layer 112 is disposed on the active layer ACT. The gate insulation layer 112 is an insulation layer for insulating the active layer ACT and the gate electrode GE. The gate insulation layer 112 may be configured as a single layer or multilayer made of silicon oxide (SiOₓ) or silicon nitride (SiNₓ). However, the present specification is not limited thereto.

The gate electrode GE is disposed on the gate insulation layer 112. The gate electrode GE may be made of an electrically conductive material, for example, copper (Cu), aluminum (Al), molybdenum (Mo), nickel (Ni), titanium (Ti), chromium (Cr), or an alloy thereof. However, the present specification is not limited thereto.

The first interlayer insulation layer 113 is disposed on the gate electrode GE. Contact holes, through which the source electrode SE and the drain electrode DE are connected to the active layer ACT, are formed in the first interlayer insulation layer 113. The first interlayer insulation layer 113 is an insulation layer for protecting the first interlayer insulation layer 113 and components disposed below the first interlayer insulation layer 113. The first interlayer insulation layer 113 may be configured as a single layer or multilayer made of silicon oxide (SiOₓ) or silicon nitride (SiNₓ). However, the present specification is not limited thereto.

A capacitor electrode C2 is disposed on the first interlayer insulation layer 113. The capacitor electrode C2 may be disposed to overlap the gate electrode GE with the first interlayer insulation layer 113 interposed therebetween.

The second interlayer insulation layer 114 is disposed on the capacitor electrode C2. Contact holes, through which the source electrode SE and the drain electrode DE are connected to the active layer ACT, are formed in the second interlayer insulation layer 114. The second interlayer insulation layer 114 is an insulation layer for protecting components disposed below the second interlayer insulation layer 114. The second interlayer insulation layer 114 may be configured as a single layer or multilayer made of silicon oxide (SiOₓ) or silicon nitride (SiNₓ). However, the present specification is not limited thereto.

The source electrode SE and the drain electrode DE are disposed on the second interlayer insulation layer 114 and electrically connected to the active layer ACT. The source electrode SE and the drain electrode DE may each be made of an electrically conductive material, for example, copper (Cu), aluminum (Al), molybdenum (Mo), nickel (Ni), titanium (Ti), chromium (Cr), or an alloy thereof. For example, the source electrode SE and the drain electrode DE may each have a structure in which molybdenum (Mo), aluminum (Al), and molybdenum (Mo) are layered. However, the present specification is not limited thereto.

Meanwhile, the source electrode SE and the drain electrode DE may have a larger thickness than the light-blocking layer LS. Because the light-blocking layer LS is disposed adjacent to the substrate 110, which makes it difficult for the light-blocking layer LS to have a large thickness. In contrast, the source electrode SE and the drain electrode DE are disposed to be closer to an upper portion of the substrate 110 than the light-blocking layer LS. Therefore, a thickness of each of the source electrode SE and the drain electrode DE may be larger than a thickness of the light-blocking layer LS. However, the present specification is not limited thereto.

Meanwhile, in the present specification, the configuration has been described in which the first interlayer insulation layer 113 and the second interlayer insulation layer 114, i.e., the plurality of insulation layers is disposed between the gate electrode GE, the source electrode SE, and the drain electrode DE. However, only a single insulation layer may be disposed between the gate electrode GE, the source electrode SE, and the drain electrode DE. However, the present specification is not limited thereto.

Further, as illustrated in the drawings, in case that the plurality of insulation layers, such as the first interlayer insulation layer 113 and the second interlayer insulation layer 114, is disposed between the gate electrode GE, the source electrode SE, and the drain electrode DE, an electrode may be additionally formed between the first interlayer insulation layer 113 and the second interlayer insulation layer 114. The additionally formed electrode may define a capacitor together with other components disposed on a lower portion of the first interlayer insulation layer 113 or an upper portion of the second interlayer insulation layer 114.

The auxiliary electrode LE is disposed on the gate insulation layer 112. The auxiliary electrode LE is an electrode that electrically connects the light-blocking layer LS disposed below the buffer layer 111, to any one of the source electrode SE and the drain electrode DE on the second interlayer insulation layer 114. For example, the light-blocking layer LS may be electrically connected to any one of the source electrode SE and the drain electrode DE through the auxiliary electrode LE so as not to be operated as a floating gate, thereby reducing or minimizing a change in threshold voltage of the driving transistor DT caused by the floating light-blocking layer LS. The drawing illustrates that the light-blocking layer LS is connected to the source electrode SE. However, the light-blocking layer LS may be connected to the drain electrode DE. However, the present specification is not limited thereto.

The first planarization layer 115 is disposed on the driving transistor DT. The first planarization layer 115 may planarize an upper portion of the substrate 110 on which the driving transistor DT is disposed. The first planarization layer 115 may be configured as a single layer or multilayer and made of a photoresist or an acrylic-based organic material, for example. However, the present specification is not limited thereto.

The plurality of reflective electrodes RE spaced apart from one another is disposed on the first planarization layer 115. The plurality of reflective electrodes RE may serve to electrically connect the light-emitting element LED to the plurality of power lines VL and the driving transistor DT and serve as a reflective plate that reflects light emitted from the light-emitting element LED, to an upper portion of the light-emitting element LED. The plurality of reflective electrodes RE may each be made of an electrically conductive material having excellent reflection performance and reflect the light emitted from the light-emitting element LED, toward the upper portion of the light-emitting element LED.

For example, the plurality of reflective electrodes RE may each be made of an electrically conductive material, for example, copper (Cu), aluminum (Al), molybdenum (Mo), nickel (Ni), titanium (Ti), chromium (Cr), or an alloy thereof. Meanwhile, the plurality of reflective electrodes RE may each have a structure in which indium tin oxide (ITO), aluminum (Al), and molybdenum (Mo) are layered. However, the present specification is not limited thereto.

The plurality of reflective electrodes RE may be larger in thickness than the light-blocking layer LS. Because the light-blocking layer LS is disposed adjacent to the substrate 110, which makes it difficult for the light-blocking layer LS to have a large thickness. In contrast, the plurality of reflective electrodes RE is disposed to be closer to the upper portion of the substrate 110 than the light-blocking layer LS. Therefore, a thickness of each of the plurality of reflective electrodes RE may be larger than a thickness of the light-blocking layer LS.

The plurality of reflective electrodes RE may be made of aluminum (Al).

The plurality of reflective electrodes RE includes a first reflective electrode RE1 and a second reflective electrode RE2. The first reflective electrode RE1 may electrically connect the driving transistor DT and the light-emitting element LED. The first reflective electrode RE1 may be connected to the source electrode SE or the drain electrode DE of the driving transistor DT through a contact hole formed in the first planarization layer 115. Further, the first reflective electrode RE1 may be electrically connected to a first electrode and a first semiconductor layer of the light-emitting element LED through the first connection electrode CE1 to be described below.

The second reflective electrode RE2 may be electrically connected to a second electrode 125 and a second semiconductor layer 123 of each of the plurality of light-emitting elements LED through a second connection electrode CE2 to be described below.

The passivation layer 119 is disposed on the plurality of reflective electrodes RE. The passivation layer 119 has contact holes through which the plurality of reflective electrodes RE are respectively connected to the first connection electrode CE1 and the second connection electrode CE2. The passivation layer 119 may be an insulation layer for protecting components disposed below the passivation layer 119. The passivation layer 119 may be configured as a single layer or multilayer made of silicon oxide (SiOₓ) or silicon nitride (SiNₓ). However, the present specification is not limited thereto.

The bonding layer 116 is disposed on the plurality of reflective electrodes RE. The front surface of the substrate 110 may be coated with the bonding layer 116, and the bonding layer 116 may fix the light-emitting element LED disposed on the bonding layer 116. For example, the bonding layer 116 may be made of any one material selected from adhesive polymer, epoxy resist, UV resin, a polyimide-based material, an acrylate-based material, a urethane-based material, and polydimethylsiloxane (PDMS). However, the present specification is not limited thereto.

The plurality of light-emitting elements LED is provided on the bonding layer 116 and disposed in each of the plurality of subpixels SP. The plurality of light-emitting elements LED may be elements configured to emit light by using an electric current and include the light-emitting elements LED configured to emit red light, green light, blue light, and the like. The plurality of light-emitting elements LED may implement light with various colors including white by using a combination of red light, green light, blue light, and the like. For example, the plurality of light-emitting elements LED may each be a light-emitting diode (LED) or a micro LED. However, the present specification is not limited thereto.

The plurality of light-emitting elements LED each includes a first semiconductor layer 121, a light-emitting layer 122, the second semiconductor layer 123, a first electrode 124, the second electrode 125, and an encapsulation layer 126.

With reference to FIG. 4 together, the first semiconductor layer 121 of the light-emitting element LED is disposed on the bonding layer 116, and the second semiconductor layer 123 is disposed on the first semiconductor layer 121. The first semiconductor layer 121 and the second semiconductor layer 123 may each be a layer formed by doping a particular material with n-type and p-type impurities. For example, the first semiconductor layer 121 and the second semiconductor layer 123 may each be a layer formed by doping a material, such as gallium nitride (GaN), indium aluminum phosphide (InAlP), or gallium arsenide (GaAs) with n-type and p-type impurities. Further, the p-type impurity may be magnesium, zinc (Zn), beryllium (Be), or the like. The n-type impurity may be silicon (Si), germanium, tin (Sn), or the like. However, the present specification is not limited thereto.

The light-emitting layer 122 is disposed between the first semiconductor layer 121 and the second semiconductor layer 123. The light-emitting layer 122 may emit light by receiving positive holes and electrons from the first semiconductor layer 121 and the second semiconductor layer 123. The light-emitting layer 122 may be configured as a single layer or a multi-quantum well (MQW) structure. For example, the light-emitting layer 122 may be made of indium gallium nitride (InGaN), gallium nitride (GaN), or the like. However, the present specification is not limited thereto.

The first electrode 124 is disposed on the first semiconductor layer 121. The first electrode 124 is an electrode that electrically connects the driving transistor DT and the first semiconductor layer 121. The first electrode 124 may be disposed on a top surface of the first semiconductor layer 121 exposed from the light-emitting layer 122 and the second semiconductor layer 123. The first electrode 124 may be made of an electrically conductive material, for example, a transparent conductive material such as indium tin oxide (ITO) or indium zinc oxide (IZO) or an opaque conductive material such as titanium (Ti), gold (Au), silver (Ag), copper (Cu), or an alloy thereof. However, the present specification is not limited thereto.

The second electrode 125 is disposed on the second semiconductor layer 123. The second electrode 125 may be disposed on a top surface of the second semiconductor layer 123. The second electrode 125 may be made of an electrically conductive material, for example, a transparent conductive material such as indium tin oxide (ITO) or indium zinc oxide (IZO) or an opaque conductive material such as titanium (Ti), gold (Au), silver (Ag), copper (Cu), or an alloy thereof. However, the present specification is not limited thereto.

Next, the encapsulation layer 126 is disposed to surround the first semiconductor layer 121, the light-emitting layer 122, the second semiconductor layer 123, the first electrode 124, and the second electrode 125. The encapsulation layer 126 may be made of an insulating material and protect the first semiconductor layer 121, the light-emitting layer 122, and the second semiconductor layer 123. Further, a contact hole, through which the first electrode 124 and the second electrode 125 are exposed, may be formed in the encapsulation layer 126, such that the first connection electrode CE1, the second connection electrode CE2, the first electrode 124, and the second electrode 125 may be electrically connected.

The second planarization layer 117 and the third planarization layer 118 are disposed on the bonding layer 116. The second planarization layer 117 may partially overlap the side surfaces of the plurality of light-emitting elements LED and fix and protect the plurality of light-emitting elements LED. Specifically, FIG. 4 illustrates that the encapsulation layer 126 surrounds the entire side surface of the first semiconductor layer 121. However, a part of the side surface of the first semiconductor layer 121 may be exposed from the encapsulation layer 126. The light-emitting element LED manufactured on a wafer may be separated from the wafer and transferred to the display panel PN. However, a part of the encapsulation layer 126 may be torn during a process of separating the light-emitting element LED from the wafer. For example, a part of the encapsulation layer 126 adjacent to a lower edge of the first semiconductor layer 121 of the light-emitting element LED may be torn during the process of separating the light-emitting element LED from the wafer, such that a part of a lower side surface of the first semiconductor layer 121 may be exposed to the outside. However, even though the lower portion of the light-emitting element LED is exposed from the encapsulation layer 126, the first connection electrode CE1 and the second connection electrode CE2 are formed after the second planarization layer 117, which covers the side surface of the first semiconductor layer 121, is formed, thereby reducing or minimizing a short circuit defect.

In addition, the third planarization layer 118 may be formed to cover an upper portion of the second planarization layer 117 and an upper portion of the light-emitting clement LED. A contact hole, through which the first electrode 124 and the second electrode 125 of the light-emitting element LED are exposed, may be formed in the third planarization layer 118. The first electrode 124 and the second electrode 125 of the light-emitting element LED may be exposed from the third planarization layer 118, and the third planarization layer 118 may be partially disposed in an area between the first electrode 124 and the second electrode 125, thereby reducing or minimizing a short circuit defect.

The second planarization layer 117 and the third planarization layer 118 may each be configured as a single layer or multilayer and made of a photoresist or an acrylic-based organic material, for example. However, the present specification is not limited thereto. Meanwhile, in the present specification, the configuration has been described in which the second planarization layer 117 and the third planarization layer 118 are disposed. However, the planarization layer may be configured as a single layer. However, the present specification is not limited thereto.

The plurality of connection electrodes CE is disposed on the third planarization layer 118. The plurality of connection electrodes CE includes the plurality of first connection electrodes CE1 and the plurality of second connection electrodes CE2.

The first connection electrodes CE1 are electrodes that are respectively disposed in the plurality of subpixels SP and electrically connect the light-emitting elements LED and the driving transistors DT. The first connection electrode CE1 may be connected to the first reflective electrode REI through contact holes formed in the third planarization layer 118, the second planarization layer 117, and the bonding layer 116. Therefore, the first connection electrode CE1 may be electrically connected to any one of the source electrode SE and the drain electrode DE of the driving transistor DT through the first reflective electrode RE1. Further, the first connection electrode CE1 may be connected to the first electrode 124 of each of the plurality of light-emitting elements LED through the contact hole formed in the third planarization layer 118. Therefore, the first connection electrode CE1 may electrically connect the driving transistor DT and the first electrode 124 and the first semiconductor layer 121 of each of the plurality of light-emitting elements LED.

The second connection electrode CE2 may be connected to the second reflective electrode RE2 through contact holes formed in the third planarization layer 118, the second planarization layer 117, and the bonding layer 116. Further, the second connection electrode CE2 may be connected to the second electrode 125 of each of the plurality of light-emitting elements LED through the contact hole formed in the third planarization layer 118.

Meanwhile, the first connection electrode CE1, which connects the driving transistor DT and the light-emitting element LED disposed in each of the plurality of subpixels SP, may be independently disposed in each of the plurality of subpixels SP.

Meanwhile, the plurality of light-emitting elements LED may be connected to the plurality of power lines VL. For example, the plurality of light-emitting elements LED may be respectively connected to the plurality of power lines VL through the first connection electrode CE1 and the second connection electrode CE2.

The plurality of power lines VL may each include a first sub-power line extending in the first direction DR1 and disposed on the same layer as the light-blocking layer LS, a second sub-power line extending in a second direction DR2 disposed on the same layer as the electrodes of the plurality of transistors DT, and a third sub-power line extending in the first direction DR1 and disposed on the same layer as the plurality of reflective electrodes RE. Therefore, the plurality of light-emitting elements LED may be connected to any one of the first sub-power line, the second sub-power line, and the third sub-power line through the first connection electrode CE1 and the second connection electrode CE2.

With reference to FIG. 3, the plurality of power lines VL is disposed on the substrate 110 of the display panel PN.

Meanwhile, the plurality of power lines VL may include the plurality of first power lines VL1, and the plurality of second power lines VL2 to which voltages, which are different from voltages applied to the plurality of first power lines VL1, are applied.

The plurality of first power lines VL1 is disposed on the substrate 110 of the display panel PN. At least some of the plurality of first power lines VL1 may extend from first power pads of the plurality of first pads PAD1 and the plurality of second pads PAD2 toward the plurality of subpixels SP and transmit high-potential power voltages to the pixel circuits of the plurality of subpixels SP. Therefore, the plurality of first power lines VL1 may be high-potential power lines.

The plurality of power lines VL may each include the first sub-power line, the second sub-power line, and the third sub-power line. The plurality of first power lines VL1 may each include a first-first sub-power line VL1a that is the first sub-power line, a first-second sub-power line VL1b that is the second sub-power line, and a first-third sub-power line VL1c that is the third sub-power line.

With reference to FIG. 5, the first-first sub-power line VL1a of the first power line VL1 is disposed on the substrate 110. The first-first sub-power line VL1a may be disposed on the same layer as the light-blocking layer LS. Therefore, the first-first sub-power line VL1a may be made of the same material as the light-blocking layer LS. For example, the first-first sub-power line VL1a may be made of molybdenum (Mo). However, the present specification is not limited thereto.

With reference to FIG. 3 together, the first-first sub-power line VL1a may extend in the first direction DR1. In addition, the first-first sub-power line VL1a may be disposed between the pixels PX adjacent to each other in the second direction DR2.

With reference to FIG. 5, the buffer layer 111 and the gate insulation layer 112 are disposed on the first sub-power line VL1a, and a first bridge electrode BE1 is disposed on the gate insulation layer 112.

The first bridge electrode BE1 may be disposed on the same layer as the gate electrodes GE of the plurality of driving transistors DT. Therefore, the first bridge electrode BE1 may be made of the same material as the gate electrode GE. However, the present specification is not limited thereto.

With reference to B-B′ in FIG. 5, the first bridge electrode BE1 may be connected to the first-first sub-power line VL1a through a contact hole of the buffer layer 111 and a contact hole of the gate insulation layer 112. In addition, the first bridge electrode BE1 may be connected to the first-second sub-power line VL1b and electrically connect the first-first sub-power line VL1a and the first-second sub-power line VL1b.

The first interlayer insulation layer 113 and the second interlayer insulation layer 114 are disposed on the first bridge electrode BE1, and the first-second sub-power line VL1b is disposed on the second interlayer insulation layer 114.

The first-second sub-power line VL1b may be disposed on the same layer as the source electrodes SE and the drain electrodes DE of the plurality of driving transistors DT. Therefore, the first-second sub-power line VL1b may be made of the same material as the source electrode SE and the drain electrode DE. For example, the first-second sub-power line VL1b may have a structure in which molybdenum (Mo), aluminum (Al), and molybdenum (Mo) are layered. However, the present specification is not limited thereto.

With reference to FIG. 3, the first-second sub-power line VL1b may extend in the second direction DR2. Therefore, the first-second sub-power line VL1b may intersect the first-first sub-power line VL1a. In addition, the first-second sub-power line VL1b may be disposed between the pixels PX adjacent to each other in the first direction DR1.

With reference to B-B′ in FIG. 5, the first-second sub-power line VL1b may be connected to the first bridge electrode BE1 through the first interlayer insulation layer 113 and the second interlayer insulation layer 114.

Therefore, the first-first sub-power line VL1a, which extends in the first direction DR1, and the first-second sub-power line VL1b, which extends in the second direction DR2, are configured to define a mesh structure electrically by means of the first bridge electrode BE1, which may reduce the resistance of the first power line VL1 and reduce or minimize the voltage deviation.

Meanwhile, a height H2 of the first-second sub-power line VL1b may be larger than a height H1 of the first-first sub-power line VL1a. In addition, meanwhile, a width of the first-second sub-power line VL1b may be larger than a width W1 of the first-first sub-power line VL1a. However, the present specification is not limited thereto.

The passivation layer 119 and the first planarization layer 115 are disposed on the first-second sub-power line VL1b, and the first-third sub-power line VL1c is disposed on the first planarization layer 115.

The first-third sub-power line VL1c may be disposed on the same layer as the plurality of reflective electrodes RE. Therefore, the first-third sub-power line VL1c may be made of the same material as the plurality of reflective electrodes RE. For example, the plurality of first-third sub-power lines VL1c may each have a structure in which indium tin oxide (ITO), aluminum (Al), and molybdenum (Mo) are layered. However, the present specification is not limited thereto.

With reference to FIG. 3, the first-third sub-power line VL1c may extend in the first direction DR1. In addition, the first-third sub-power line VL1c may be disposed between the pixels PX adjacent to each other in the second direction DR2. Therefore, the first-third sub-power line VL1c may intersect the first-second sub-power line VL1b and extend in the same direction as the first-first sub-power line VL1a.

Meanwhile, the first-third sub-power line VL1c may be disposed to overlap the plurality of subpixels SP. For example, the first-third sub-power line VL1c may be disposed to overlap the plurality of light-emitting elements LED of the plurality of subpixels SP.

With reference to A-A′ in FIG. 5, the first-third sub-power line VL1c may be electrically connected to the first-second sub-power line VL1b through a contact hole of the first planarization layer 115 and a contact hole of the passivation layer 119.

Therefore, the first-third sub-power line VL1c and the first-second sub-power line VL1b, which extends in the second direction DR2, are configured to define a mesh structure, which may reduce the resistance of the first power line VL1 and reduce or minimize the voltage deviation.

A height of the first-third sub-power line VL1c may be larger than a height of the first-first sub-power line VL1a. However, the present specification is not limited thereto.

The plurality of second power lines VL2 is disposed on the substrate 110 of the display panel PN. At least some of the plurality of second power lines VL2 may extend from second power pads of the plurality of first pads PAD1 and the plurality of second pads PAD2 toward the plurality of subpixels SP and transmit low-potential power voltages to the pixel circuits of the plurality of subpixels SP. Therefore, the plurality of second power lines VL2 may be low-potential power lines.

The plurality of power lines VL may each include the first sub-power line, the second sub-power line, and the third sub-power line. Therefore, the plurality of second power lines VL2 may each include a second-first sub-power line VL2a that is the first sub-power line, a second-second sub-power line VL2b that is the second sub-power line, and a second-third sub-power line VL2c that is the third sub-power line.

With reference to FIG. 6, the second-first sub-power line VL2a of the second power line VL2 may be disposed on the substrate 110. The second-first sub-power line VL2a may be disposed on the same layer as the first-first sub-power line VL1a. For example, the second-first sub-power line VL2a may be disposed on the same layer as the light-blocking layer LS. Therefore, the second-first sub-power line VL2a may be made of the same material as the light-blocking layer LS. For example, the second-first sub-power line VL2a may be made of molybdenum (Mo). However, the present specification is not limited thereto.

With reference to FIG. 3, the second-first sub-power line VL2a, which is the first sub-power line of the second power line VL2, extends in the first direction DR1. Therefore, the second-first sub-power line VL2a may extend in the same direction as the first-first sub-power line VL1a. In addition, the second-first sub-power line VL2a is disposed between the pixels PX adjacent to each other in the second direction DR2.

Meanwhile, the second-first sub-power line VL2a may have the same width as the first-first sub-power line VL1a. For example, width W1 of the first-first sub-power line VL1a and width W2 of the second-first sub-power line VL2a may be the same. That is, the first sub-power lines of the plurality of first power lines VL1 and the first sub-power lines of the plurality of second power lines VL2 may have the same width. However, the present specification is not limited thereto.

With reference to FIG. 6, the buffer layer 111 and the gate insulation layer 112 are disposed on the second sub-power line VL2a, and a second bridge electrode BE2 is disposed on the gate insulation layer 112.

The second bridge electrode BE2 may be disposed on the same layer as the gate electrodes GE of the plurality of driving transistors DT. The second bridge electrode BE2 may be made of the same material as the gate electrode GE. However, the present specification is not limited thereto.

With reference to D-D′ in FIG. 6, the second bridge electrode BE2 may be connected to the second-first sub-power line VL2a through a contact hole of the buffer layer 111 and a contact hole of the gate insulation layer 112. In addition, the second bridge electrode BE2 may be connected to the second-second sub-power line VL2b and electrically connect the second-first sub-power line VL2a and the second-second sub-power line VL2b.

The first interlayer insulation layer 113 and the second interlayer insulation layer 114 are disposed on the second bridge electrode BE, and the second-second sub-power line VL2b is disposed on the second interlayer insulation layer 114.

The second-second sub-power line VL2b may be disposed on the same layer as the first-second sub-power line VL1b. The second-second sub-power line VL2b may be disposed on the same layer as the source electrodes SE and the drain electrodes DE of the plurality of driving transistors DT. Therefore, the second-second sub-power line VL2b may be made of the same material as the source electrode SE and the drain electrode DE. For example, the second-second sub-power line VL2b may have a structure in which molybdenum (Mo), aluminum (Al), and molybdenum (Mo) are layered. However, the present specification is not limited thereto.

With reference to FIG. 3, the second-second sub-power line VL2b may extend in the second direction DR2 and extend in the same direction as the first-second sub-power line VL1b. Therefore, the second-second sub-power line VL2b may intersect the second-first sub-power line VL2a. In addition, the second-second sub-power line VL2b is disposed between the pixels PX adjacent to each other in the first direction DR1. In addition, the second-second sub-power line VL2b may be disposed between the subpixels SP adjacent to each other in the first direction DR1. For example, the second-second sub-power line VL2b may be disposed between the first subpixel SP1 and the second subpixel SP2 and between the second subpixel SP2 and the third subpixel SP3.

With reference to D-D′ in FIG. 6, the second-second sub-power line VL2b may be connected to the second bridge electrode BE2 through the first interlayer insulation layer 113 and the second interlayer insulation layer 114.

Therefore, the second-first sub-power line VL2a, which extends in the first direction DR1, and the second-second sub-power line VL2b, which extends in the second direction DR2, are configured to define a mesh structure electrically by means of the second bridge electrode BE2, which may reduce the resistance of the second power line VL2 and reduce or minimize the voltage deviation.

Meanwhile, a height of the second-second sub-power line VL2b may be larger than a height of the second-first sub-power line VL2a. In addition, a width of the second-second sub-power line VL2b may be larger than a width of the second-first sub-power line VL2a. However, the present specification is not limited thereto.

The second-second sub-power line VL2b may have a width different from a width of the first-second sub-power line VL1b. For example, a width of the first-second sub-power line VL1b may be larger than a width of the second-second sub-power line VL2b. Therefore, the second sub-power line of each of the plurality of first power lines VL1 and the second sub-power line of each of the plurality of second power lines VL2 may have different widths. Specifically, a width of the second sub-power line of each of the plurality of first power lines VL1 may be larger than a width of the second sub-power line of each of the plurality of second power lines VL2. However, the present specification is not limited thereto.

The passivation layer 119 and the second planarization layer 115 are disposed on the second-second sub-power line VL2b, and the second-third sub-power line VL2c is disposed on the second planarization layer 115.

The second-third sub-power line VL2c may be disposed on the same layer as the first-third sub-power line VL1c. The second-third sub-power line VL2c may be disposed on the same layer as the plurality of reflective electrodes RE. Therefore, the second-third sub-power line VL2c may be made of the same material as the plurality of reflective electrodes RE. For example, the plurality of second-third sub-power lines VL2c may each have a structure in which indium tin oxide (ITO), aluminum (Al), and molybdenum (Mo) are layered. However, the present specification is not limited thereto.

The second-third sub-power line VL2c, which is the third sub-power line of the second power line VL2, extends in the first direction DR1. Therefore, the second-third sub-power line VL2c may extend in the same direction as the first-third sub-power line VL1c. With reference to FIG. 3, the second-third sub-power line VL2c may intersect the second-second sub-power line VL2b and extend in the same direction as the second-first sub-power line VL2a.

The second-third sub-power line VL2c may be disposed between the pixels PX adjacent to each other in the second direction DR2. Meanwhile, the second-third sub-power line VL2c may be disposed to be spaced apart from the first-third sub-power line VL1c, and the plurality of light-emitting elements LED disposed in one pixel PX may be interposed between the second-third sub-power line VL2c and the first-third sub-power line VL1c. However, the present specification is not limited thereto.

With reference to C-C′ in FIG. 6, the second-third sub-power line VL2c may be electrically connected to the second-second sub-power line VL2b through a contact hole of the second planarization layer 115 and a contact hole of the passivation layer 119. Therefore, the second-third sub-power line VL2c and the second-second sub-power line VL2b, which extends in the second direction DR2, are configured to define a mesh structure, which may reduce the resistance of the line and reduce or minimize the voltage deviation.

Meanwhile, a height of the second-third sub-power line VL2c may be larger than a height of the second-first sub-power line VL2a. However, the present specification is not limited thereto.

In addition, the second-third sub-power line VL2c may have the same width as the first-third sub-power line VL1c. That is, the third sub-power lines of the plurality of first power lines VL1 and the third sub-power lines of the plurality of second power lines VL2 may have the same width. However, the present specification is not limited thereto. In the case of a large-area display device, a severe voltage drop occurs as the distance from the pad electrode for supplying a voltage increases, and the severe voltage drop may cause a luminance deviation of the display device. For example, a voltage difference between a subpixel and a subpixel adjacent to the pad electrode may increase as a distance between the subpixel and the pad electrode for supplying the voltage increases. For this reason, a deviation between power voltages applied to the subpixels occurs, which may cause a luminance deviation in accordance with the positions of the subpixels in the display device. For this reason, there occurs a problem in that the luminances of the plurality of pixels become non-uniform because of the difference between the amounts of power voltage drops, a large amount of voltages need to be applied to compensate for the power voltage drop.

Therefore, the mesh structure is used for the power line. For example, the power line having the mesh structure, which includes the first sub-power line disposed on the same layer as the light-blocking layer and the second sub-power line disposed on the same layer as the source electrode and the drain electrode, is used. However, the light-blocking layer may have higher resistance than a metal layer disposed on the substrate. For example, the light-blocking layer is a metal layer disposed first on the substrate. Therefore, in case that a heat treatment is performed on the active layers of the plurality of driving transistors, a high-temperature treatment is performed in a state in which the light-blocking layer is disposed on the substrate. Therefore, molybdenum (Mo), which is metal with a relatively high melting point, is used for the light-blocking layer. However, molybdenum (Mo) has a relatively higher specific resistivity than the other metal layers. For example, molybdenum (Mo) has a specific resistivity about four times higher than a specific resistivity of aluminum (Al). Therefore, the resistance of the light-blocking layer may be higher than that of a metal layer disposed on another layer of the display device.

In addition, the light-blocking layer is a metal layer disposed to be closest to the substrate. In case that the light-blocking layer is disposed to have a large height, a level difference occurs between the line and the insulation layer disposed above the light-blocking layer, which degrades the quality of the layer disposed on the substrate. Therefore, there occurs a constraint to the height of the light-blocking layer. For this reason, there may occur a problem in that the resistance of the power line increases in case that the first sub-power line is disposed on the same layer as the light-blocking layer. In addition, in case that a support pin is disposed below the substrate to support the substrate during a process of manufacturing the display device, static electricity may occur between the support pin and the substrate, and the static electricity may be introduced into the light-blocking layer. Therefore, in case that the power line having the mesh structure, which includes the first sub-power line disposed on the same layer as the light-blocking layer and the second sub-power line disposed on the same layer as the source electrode and the drain electrode, is used, the use of the power line with the mesh structure may be vulnerable to the occurrence of static electricity. In particular, in case that the width of the first sub-power line is increased to reduce the resistance of the first sub-power line, a phenomenon in which the display panel is burnt by static electricity may become severe.

Therefore, in the display device 100 according to the embodiment of the present specification, the plurality of power lines VL each uses the mesh structure including the first sub-power line, the second sub-power line, and the third sub-power line. For example, in case that the plurality of power lines VL includes the plurality of first power lines VL1 and the plurality of second power lines VL2, the plurality of first power lines VL1 is each disposed to have the mesh structure including the first-first sub-power line VL1a, the first-second sub-power line VL1b, and the first-third sub-power line VL1c, and the plurality of second power lines VL2 is each disposed to have the mesh structure including the second-first sub-power line VL2a, the second-second sub-power line VL2b, and the second-third sub-power line VL2c. Therefore, it is possible to reduce the resistance of the plurality of first power lines VL1 and the resistance of the plurality of second power lines VL2 and reduce the voltage deviation. Therefore, the occurrence of the luminance deviation of the display device 100 may be reduced, and it is not necessary to apply a large amount of voltages to compensate for a voltage drop, which may improve a lifespan of the display device 100.

In addition, in the display device 100 according to the embodiment of the present specification, the third sub-power line may be made of a material disposed on the same layer as the plurality of reflective electrodes RE disposed above the plurality of electrodes disposed in the display device 100. For example, the plurality of first power lines VL1 and the plurality of second power lines VL2 respectively include the first-third sub-power line VL1c and the second-third sub-power line VL2c disposed on the same layer as the plurality of reflective electrodes RE. Therefore, the first-third sub-power line VL1c and the second-third sub-power line VL2c may be disposed relatively above the substrate 110 among the plurality of conductive layers disposed above the substrate 110, such that the first-third sub-power line VL1c and the disposed second-third sub-power line VL2c may be disposed to have large heights. In addition, in case that the plurality of reflective electrodes RE is made of a material with a relatively low specific resistivity, it is possible to solve the problem in which the resistance of the plurality of first power lines VL1 and the resistance of the plurality of second power lines VL2 are increased. For example, in case that the plurality of reflective electrodes RE includes aluminum (Al) having a specific resistivity about four times lower than that of molybdenum (Mo) constituting the light-blocking layer LS, the display device 100 may suppress a voltage drop in the plurality of first power lines VL1 and the plurality of second power lines VL2. Therefore, it is possible to suppress an RC delay that may occur in the display device 100.

In addition, in case that the first-first sub-power line VL1a and the second-first sub-power line VL2a disposed on the same layer as the light-blocking layer LS are connected to the first-second sub-power line VL1b, the first-third sub-power line VL1c, the second-second sub-power line VL2b, and the second-third sub-power line VL2c, static electricity introduced into the first-first sub-power line VL1a and the second-first sub-power line VL2a may be dispersed to the first-second sub-power line VL1b, the first-third sub-power line VL1c, the second-second sub-power line VL2b, and the second-third sub-power line VL2c. Therefore, even though static electricity occurs below the substrate 110 during the process of manufacturing the display device 100, damage to the plurality of first power lines VL1 and the plurality of second power lines VL2 may be suppressed, thereby improving the lifespan of the display device 100.

In addition, it is possible to suppress a voltage drop in the plurality of first power lines VL1 and the plurality of second power lines VL2 by increasing the widths of the first-second sub-power line VL1b, the first-third sub-power line VL1c, the second-second sub-power line VL2b, and the second-third sub-power line VL2c without increasing the widths of the first-first sub-power line VL1a and the second-first sub-power line VL2a disposed on the same layer as the light-blocking layer LS. Therefore, the widths of the first-first sub-power line VL1a and the second-first sub-power line VL2a, which are vulnerable to static electricity, are reduced, such that it is possible to solve the problem of the occurrence of static electricity caused by the increase in widths of the first-first sub-power line VL1a and the second-first sub-power line VL2a.

The exemplary embodiments of the present disclosure can also be described as follows:

According to an aspect of the present disclosure, there is provided a display device. The display device comprises a substrate on which a plurality of pixels is defined; a light-blocking layer disposed on the substrate; a plurality of transistors disposed in the plurality of pixels and on the light-blocking layer; a plurality of reflective electrodes disposed on the plurality of transistors; a plurality of light-emitting elements disposed in the plurality of pixels and on the plurality of reflective electrodes; and a plurality of power lines disposed on the substrate, wherein the plurality of power lines each comprises: a first sub-power line extending in a first direction and disposed on a same layer as the light-blocking layer; a second sub-power line extending in a second direction different from the first direction and disposed on the a same layer as electrodes of the plurality of transistors; and a third sub-power line extending in the first direction and disposed on a same layer as the plurality of reflective electrodes.

The plurality of transistors each may comprise a source electrode, a drain electrode, a gate electrode, and an active layer, and the second sub-power line may be disposed on a same layer as the source electrode and the drain electrode.

The display device may further comprise a bridge electrode configured to connect the first sub-power line and the second sub-power line, wherein the bridge electrode may be disposed on a same layer as the gate electrode.

The display device may further comprise a first insulation layer disposed between the first sub-power line and the second sub-power line; and a second insulation layer disposed between the second sub-power line and the third sub-power line, wherein the first insulation layer may be an inorganic insulation layer, and the second insulation layer is an organic insulation layer.

The plurality of power lines may comprise a plurality of first power lines and a plurality of second power lines, the plurality of first power lines are high-potential power lines, and the plurality of second power lines are low-potential power lines.

The first sub-power lines of the plurality of first power lines and the first sub-power lines of the plurality of second power lines may have a same width, the third sub-power lines of the plurality of first power lines and the third sub-power lines of the plurality of second power lines may have a same width, and the second sub-power line of each of the plurality of first power lines and the second sub-power line of each of plurality of second power lines may have different widths.

A width of the second sub-power line of each of the plurality of first power lines may be larger than a width of the second sub-power line of each of the plurality of second power lines.

The plurality of light-emitting elements may be disposed in the first direction.

The first sub-power line may be made of molybdenum (Mo), the second sub-power line may be configured as a layer in which molybdenum (Mo), aluminum (Al), and molybdenum (Mo) are layered, and the third sub-power line may be configured as a layer in which indium tin oxide (ITO), aluminum (Al), and molybdenum (Mo) are layered.

A height of the second sub-power line and a height of the third sub-power line may be larger than a height of the first sub-power line.

A width of the second sub-power line and a width of the third sub-power line may be larger than a width of the first sub-power line.

Although the exemplary embodiments of the present disclosure have been described in detail with reference to the accompanying drawings, the present disclosure is not limited thereto and may be embodied in many different forms without departing from the technical concept of the present disclosure. Therefore, the exemplary embodiments of the present disclosure are provided for illustrative purposes only but not intended to limit the technical concept of the present disclosure. The scope of the technical concept of the present disclosure is not limited thereto. Therefore, it should be understood that the above-described exemplary embodiments are illustrative in all aspects and do not limit the present disclosure. The protective scope of the present disclosure should be construed based on the following claims, and all the technical concepts in the equivalent scope thereof should be construed as falling within the scope of the present disclosure.

The various embodiments described above can be combined to provide further embodiments. All of the U.S. patents, U.S. patent application publications, U.S. patent applications, foreign patents, foreign patent applications and non-patent publications referred to in this specification and/or listed in the Application Data Sheet are incorporated herein by reference, in their entirety. Aspects of the embodiments can be modified, if necessary to employ concepts of the various patents, applications and publications to provide yet further embodiments.

These and other changes can be made to the embodiments in light of the above-detailed description. In general, in the following claims, the terms used should not be construed to limit the claims to the specific embodiments disclosed in the specification and the claims, but should be construed to include all possible embodiments along with the full scope of equivalents to which such claims are entitled. Accordingly, the claims are not limited by the disclosure.

1. A display device comprising:
a substrate;
a plurality of pixels on the substrate;
a light-blocking layer on the substrate;
a plurality of transistors disposed in the plurality of pixels and on the light-blocking layer;
a plurality of reflective electrodes on the plurality of transistors;
a plurality of light-emitting elements disposed in the plurality of pixels and on the plurality of reflective electrodes; and
a plurality of power lines on the substrate,
wherein the plurality of power lines each comprises:
a first sub-power line extending in a first direction and on a same layer as the light-blocking layer;
a second sub-power line extending in a second direction different from the first direction and on a same layer as electrodes of the plurality of transistors; and
a third sub-power line extending in the first direction and on a same layer as the plurality of reflective electrodes.

2. The display device of claim 1, wherein the plurality of transistors each comprises a source electrode, a drain electrode, a gate electrode, and an active layer, and the second sub-power line is on a same layer as the source electrode and the drain electrode.

3. The display device of claim 2, further comprising:
a bridge electrode configured to electrically connect the first sub-power line and the second sub-power line,
wherein the bridge electrode is on a same layer as the gate electrode.

4. The display device of claim 1, further comprising:
a first insulation layer between the first sub-power line and the second sub-power line; and
a second insulation layer between the second sub-power line and the third sub-power line,
wherein the first insulation layer is an inorganic insulation layer, and the second insulation layer is an organic insulation layer.

5. The display device of claim 1, wherein the plurality of power lines comprises a plurality of first power lines and a plurality of second power lines, the plurality of first power lines are high-potential power lines, and the plurality of second power lines are low-potential power lines.

6. The display device of claim 5, wherein the first sub-power lines of the plurality of first power lines and the first sub-power lines of the plurality of second power lines have a same width, the third sub-power lines of the plurality of first power lines and the third sub-power lines of the plurality of second power lines have a same width, and the second sub-power line of each of the plurality of first power lines and the second sub-power line of each of plurality of second power lines have different widths.

7. The display device of claim 6, wherein a width of the second sub-power line of each of the plurality of first power lines is larger than a width of the second sub-power line of each of the plurality of second power lines.

8. The display device of claim 6, wherein the plurality of light-emitting elements is disposed in the first direction.

9. The display device of claim 1, wherein the first sub-power line is made of molybdenum, the second sub-power line is configured as a layer in which molybdenum, aluminum, and molybdenum are layered, and the third sub-power line is configured as a layer in which indium tin oxide, aluminum, and molybdenum are layered.

10. The display device of claim 1, wherein a height of the second sub-power line and a height of the third sub-power line are larger than a height of the first sub-power line.

11. The display device of claim 1, wherein a width of the second sub-power line and a width of the third sub-power line are larger than a width of the first sub-power line.
